(19) United States
(12) Patent Application Publication
(10) Pub. No.: US 2024/0105477 A1
(43) Pub. Date: Mar. 28, 2024

(54) SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventors: Naofumi OHASHI, Toyama-shi (JP); Toshiyuki KIKUCHI, Toyama-shi (JP); Hideto YAMAGUCHI, Toyama-shi (JP); Masamichi YACHI, Toyama-shi (JP)

(73) Assignee: Kokusai Electric Corporation, Tokyo (JP)

(21) Appl. No.: 18/469,717

(22) Filed: Sep. 19, 2023

(30) Foreign Application Priority Data
Sep. 22, 2022 (JP) 2022-150788

(51) Int. Cl. H01L 21/67; H01J 37/32

(52) U.S. Cl. CPC H01L 21/67167; H01J 37/32449; H01L 21/6719; H01L 21/67253

(57) ABSTRACT

There is provided a technique that includes: a process chamber in which a substrate is processed; an exhaust controller configured to control a gas flow path through which a plurality of exhausts in parallel is connected to the process chamber and a gas flow in the gas flow path; an output controller configured to control output of each of the exhausts; and a controller configured to be capable of controlling the exhaust controller and the output controller.

### CROSS-REFERENCE TO RELATED APPLICATIONS

This application is based upon and claims the benefit of priority from Japanese Patent Application No. 2022-150788, filed on Sep. 22, 2022, the entire contents of which are incorporated herein by reference.

### FIELD

The present disclosure relates to a substrate processing apparatus, a method of processing a substrate, a method of manufacturing a semiconductor device, and a recording medium.

### DESCRIPTION OF THE RELATED ART

In some embodiments, in a substrate processing apparatus, such as a semiconductor manufacturing apparatus, a vacuum pump is connected for each process chamber in which a substrate is processed, and exhaustion of each process chamber is performed by the corresponding vacuum pump.

### SUMMARY

The present disclosure is directed to providing a technique enabling a reduction in the power consumption of a vacuum pump.

According to an embodiment of the present disclosure, there is provided a technique that includes:
a process chamber in which a substrate is processed;
an exhaust controller configured to control a gas flow path through which a plurality of exhausts in parallel is connected to the process chamber and a gas flow in the gas flow path;
an output controller configured to control output of each of the exhausts; and
a controller configured to be capable of controlling the exhaust controller and the output controller.

### BRIEF DESCRIPTION OF THE DRAWINGS

FIG. 1 illustrates a schematic configuration of a substrate processing apparatus according to an embodiment of the present disclosure.

FIG. 2 illustrates a schematic configuration of gas suppliers and a gas exhauster in the substrate processing apparatus illustrated in FIG. 1.

FIG. 3 is a flowchart of a substrate processing process that the substrate processing apparatus illustrated in FIG. 1 performs.

FIG. 4A illustrates a connection example in which three vacuum pumps are connected to four process chambers through the gas exhauster illustrated in FIG. 2.

FIG. 4B illustrates a schematic configuration of a gas exhauster in a substrate processing apparatus in a comparative example.

FIG. 5A illustrates a connection example in which two vacuum pumps are connected to the four process chambers through the gas exhauster illustrated in FIG. 2.

FIG. 5B illustrates the state of the gas exhauster after a switch is made in the gas flow path in response to detection of abnormality in a vacuum pump in the state of the gas exhauster illustrated in FIG. 5A.

FIG. 5C illustrates the state of the gas exhauster after a switch is made in the gas flow path and changes are made in the outputs of vacuum pumps in the state of the gas exhauster illustrated in FIG. 5B.

FIG. 6A illustrates a connection example in which three vacuum pumps are connected to the four process chambers through the gas exhauster illustrated in FIG. 2.

FIG. 6B illustrates the state of the gas exhauster after changes are made in the outputs of vacuum pumps in response to detection of abnormality in a vacuum pump in the state of the gas exhauster illustrated in FIG. 6A.

FIG. 7A illustrates a connection example in which three vacuum pumps are connected to the four process chambers through the gas exhauster illustrated in FIG. 2.

FIG. 7B illustrates the state of the gas exhauster after a switch is made in the gas flow path in the state of the gas exhauster illustrated in FIG. 7A.

FIG. 8A illustrates a connection example in which four vacuum pumps are connected to the four process chambers through the gas exhauster illustrated in FIG. 2.

FIG. 8B illustrates the state of the gas exhauster after a switch is made in the gas flow path and a change is made in the output of a vacuum pump in the state of the gas exhauster illustrated in FIG. 8A.

FIG. 9A illustrates a connection example in which three vacuum pumps are connected to the four process chambers through the gas exhauster illustrated in FIG. 2.

FIG. 9B illustrates the state of the gas exhauster after a switch is made in the gas flow path and changes are made in the outputs of vacuum pumps in the state of the gas exhauster illustrated in FIG. 9A.

FIG. 10A illustrates a connection example in which the four vacuum pumps are connected to the four process chambers through the gas exhauster illustrated in FIG. 2.

FIG. 10B illustrates the state of the gas exhauster after changes are made in the outputs of the vacuum pumps in the state of the gas exhauster illustrated in FIG. 10A.

### DETAILED DESCRIPTION

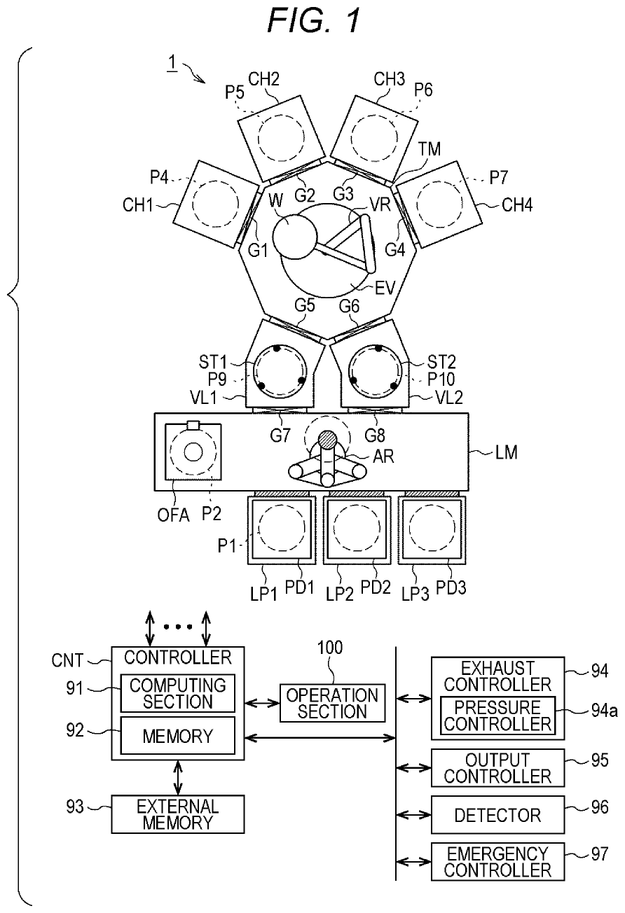

An embodiment of the present disclosure will be described below mainly with reference to FIGS. 1 to 4A and FIGS. 5A to 10B. In all the drawings, the same or corresponding constituents are denoted with the same or corresponding reference signs, and thus duplicate descriptions will be omitted. Note that the drawings used in the following description are all schematic and thus, for example, the dimensional relationship between each constituent element and the ratio between each constituent element illustrated in the drawings do not necessarily coincide with realities. In addition, for example, a plurality of drawings does not necessarily coincide with each other in the dimensional relationship between each constituent element or in the ratio between each constituent element. Unless otherwise noted in the specification, each constituent element is not limited to one in number and thus may be two or more in number.

(1) Configuration of Substrate Processing Apparatus

A substrate processing apparatus 1 according to the present embodiment is for use in a process of manufacturing a semiconductor device and serves as a cluster-type apparatus including a plurality of single-wafer processing units, in which a single substrate to be processed is processed at a time in each single-wafer processing unit. An example of such a substrate to be processed is a semiconductor wafer substrate (hereinafter, simply referred to as a “wafer”) to have a semiconductor device, such as a semiconductor integrated circuit, built thereon.

As illustrated in FIG. 1, the substrate processing apparatus 1 includes a vacuum transfer chamber (transfer chamber) TM, which can be made vacuum-airtight, serving as a transfer chamber, vacuum lock chambers (load lock chambers) VL1 and VL2 serving as reserve chambers, and process chambers (process modules) CH1 to CH4 each serving as a process chamber in which a wafer W is processed. The vacuum lock chambers VL1 and VL2 and the process chambers CH1 to CH4 are disposed in a cluster along the outer circumference of the vacuum transfer chamber TM. Hereinafter, if no distinction is particularly needed between the process chambers CH1 to CH4, simply referred to as a “process chamber CH”.

The vacuum transfer chamber TM has a load lock chamber structure resistant to pressure (negative pressure) less than atmospheric pressure, such as a vacuum. Note that, in the present embodiment, the housing of the vacuum transfer chamber TM is, for example, octagonally boxy in shape in plan view.

A vacuum transfer robot VR serving as a transferrer is provided inside the vacuum transfer chamber TM. The vacuum transfer robot VR has an arm provided with a substrate placement section and places a wafer W on the substrate placement section to transfer the wafer W mutually between the vacuum lock chamber VL1 or VL2 and any process chamber CH. Note that the vacuum transfer robot VR can be raised or lowered by an elevator EV with the vacuum transfer chamber TM kept airtight.

In each process chamber CH, performed is film-forming processing to form a thin film, such as an oxide film, a nitride film, or a metal film, onto a wafer W.

The process chambers CH1 to CH4 can be made in communication with the vacuum transfer chamber TM through gate valves G1 to G4, respectively. For example, in order to process a wafer Win the process chamber CH1, after the atmosphere in the process chamber CH1 is made equivalent to that in the vacuum transfer chamber TM, the gate valve G1 is made open and then the wafer W is transferred to the process chamber CH1, followed by making the gate valve G1 shut. Then, predetermined processing is performed in the process chamber CH1. After that, the atmosphere in the process chamber CH1 is made equivalent to that in the vacuum transfer chamber TM again, and then the gate valve G1 is made open. After the wafer W is unloaded from the process chamber CH1, the gate valve G1 is made shut. Similarly to the gate valve G1, operating the gate valves G2 to G4 to open/shut enables formation of atmosphere for processing a wafer W in each of the process chambers CH2 to CH4.

The vacuum lock chambers VL1 and VL2 each function as a reserve chamber for loading a wafer W into the vacuum transfer chamber TM or function as a reserve chamber for unloading a wafer W from the vacuum transfer chamber TM. Inside the vacuum lock chambers VL1 and VL2, respectively, provided are buffer stages ST1 and ST2 that each temporarily support a wafer W, for substrate loading/substrate unloading. Although not illustrated, the vacuum lock chambers VL1 and VL2 are each provided with a cooling function to cool a wafer W. Note that, separately from the vacuum lock chambers VL1 and VL2, a cooling chamber may be provided.

The vacuum lock chambers VL1 and VL2 can be made in communication with the vacuum transfer chamber TM through gate valves G5 and G6, respectively, and can be made in communication with an atmospheric transfer chamber LM, described later, through gate valves G7 and G8, respectively. For retention of the vacuum state of the vacuum transfer chamber TM and the atmospheric pressure state of the atmospheric transfer chamber LM, one of the gate valves G5 and G7 with which the vacuum lock chamber VL1 is provided remains shut and one of the gate valves G6 and G8 with which the vacuum lock chamber VL2 is provided remains shut, that is, the gate valves G5 and G7 are not allowed to remain open simultaneously and the gate valves G6 and G8 are not allowed to remain open simultaneously. For example, in order to open the gate valve G5 on the side of location of the vacuum transfer chamber TM, the atmosphere in the vacuum lock chamber VL1 is made vacuum with the opposite gate valve G7 shut. Note that the term “vacuum” in the present specification indicates an industrial vacuum. In order to open the gate valve G7 on the side of location of the atmospheric transfer chamber LM, the atmosphere in the vacuum lock chamber VL1 is brought at atmospheric pressure with the opposite gate valve G5 shut. Therefore, opening the gate valves G7 and G8 with the gate valves G5 and G6 shut enables transfer of a wafer W between the vacuum lock chamber VL1 or VL2 and the atmospheric transfer chamber LM, with the vacuum transfer chamber TM kept vacuum-airtight.

The vacuum lock chambers VL1 and VL2 each have a load lock chamber structure resistant to negative pressure less than atmospheric pressure, such as a vacuum, and thus can each have its inside vacuum-exhausted. Therefore, after the vacuum lock chambers VL1 and VL2 each have its inside vacuum-exhausted with the gate valves G7 and G8 shut, opening the gate valves G5 and G6 enables transfer of a wafer W between the vacuum lock chamber VL1 or VL2 and the vacuum transfer chamber TM, with the vacuum transfer chamber TM kept vacuum.

The substrate processing apparatus 1 further includes the atmospheric transfer chamber LM connected to the vacuum lock chambers VL1 and VL2 and load ports LP1 to LP3 serving as substrate storages connected to the atmospheric transfer chamber LM. Pods PD1 to PD3 serving as substrate storage containers are placed on the load ports LP1 to LP3, respectively. Inside each of the pods PD1 to PD3, provided is a plurality of slots serving as storage sections each for housing a wafer W. Hereinafter, if no distinction is particularly needed between the load ports LP1 to LP3, simply referred to as a “load port LP”. In addition, if no distinction is particularly needed between the pods PD1 to PD3, simply referred to as a “pod PD”.

Inside the atmospheric transfer chamber LM, provided is one atmospheric transfer robot AR serving as an atmospheric transferrer. The atmospheric transfer robot AR transfers a wafer W mutually between the vacuum lock chamber VL1 or VL2 and the pod PD placed on any load port LP. The atmospheric transfer robot AR has an arm provided with a substrate placement section, similarly to the vacuum transfer robot VR.

Note that, inside the atmospheric transfer chamber LM, provided is an orientation flat aligner OFA, serving as a compensator for substrate position, that aligns the crystal orientation of a wafer W. Alternatively, provided is a notch aligner that aligns the crystal orientation of a wafer W based on a notch formed on the wafer W, instead of the orientation flat aligner OFA.

Each constituent described above is connected to a controller CNT. The controller CNT includes at least a computing section 91 and a memory 92. An operation section (inputter) 100 that receives an operation from a user (operator) is connected to the controller CNT. The operation section 100 includes a display and a keyboard in combination or a touch screen. The operation section 100 receives various types of instructions for operating the substrate processing apparatus 1 from the operator and then outputs the various types of instructions to the controller CNT and also displays information regarding the substrate processing apparatus 1 (e.g., operation information or abnormality information) output from the controller CNT. Thus, a change can be made in a process recipe.

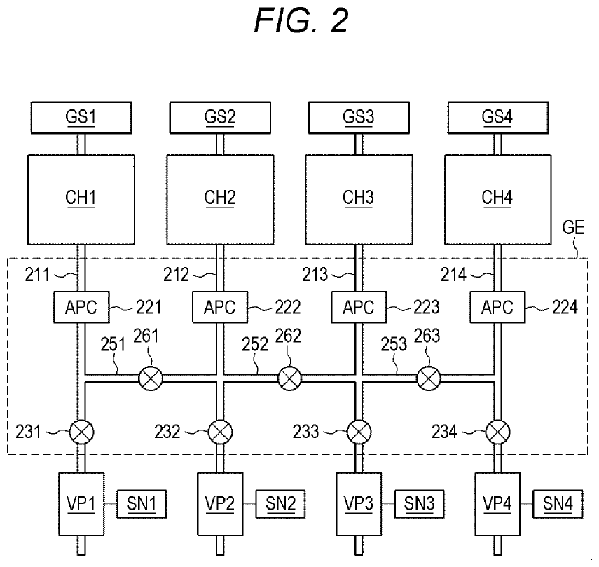

In addition to each constituent described above, gas suppliers GS1 to GS4 illustrated in FIG. 2, an exhaust controller 94, an output controller 95, a detector 96, and an emergency controller 97 are connected to the controller CNT. The controller CNT calls a program or recipe from the memory 92 in response to an instruction input from the operator through the operation section 100 or an instruction from a higher-level controller (not illustrated), and controls the operation of each constituent in accordance with the description of the program or recipe to perform desired processing to a wafer W.

Note that the controller CNT may be a dedicated computer or may be a general-purpose computer. For example, an external memory (e.g., a magnetic tape, a magnetic disk, such as a flexible disk or hard disk, an optical disc, such as a CD or DVD, a magneto-optical disc, such as an MO, or a semiconductor memory, such as a USB memory or memory card) 93 storing the above program is prepared and then the program is installed on a general-purpose computer through the external memory 93, so that the controller CNT can be achieved.

For supply of the program to a computer, the supply through the external memory 93 is not limiting. For example, the program may be supplied through the Internet or a dedicated line, instead of through the external memory 93. Note that the memory 92 and the external memory 93 each serve as a computer-readable recording medium. Hereinafter, such memories are collectively and simply referred to as a recording medium. Note that, in the present specification, in some cases, the term “recording medium” indicates only the memory 92, only the external memory 93, or both thereof.

Next, a gas supplier and a gas exhauster for the substrate processing apparatus 1 will be described. As illustrated in FIG. 2, the gas suppliers GS1 to GS4 are connected to the process chambers CH1 to CH4, respectively. Hereinafter, if no distinction is particularly needed between the gas suppliers GS1 to GS4, simply referred to as a “gas supplier GS”.

The gas suppliers GS each include a valve (disc) that turns ON/OFF the supply of processing gas and a mass flow controller (MFC) that controls the flow rate of processing gas. The gas suppliers GS each supply the corresponding process chamber CH with gas for processing to a wafer W or gas for cleaning processing to the corresponding process chamber CH. The gas suppliers GS may each include a supply source for the processing gas. For example, the processing to a wafer W corresponds to the film-forming processing described above. The gas suppliers GS each include at least a valve and an MFC that control the supply of source gas and the flow rate of source gas, respectively, a valve and an MFC that control the supply of reactant gas and the flow rate of reactant gas, respectively, and a valve and an MFC that control the supply of inert gas and the flow rate of inert gas, respectively. The gas suppliers GS may each include a supply source for the source gas, a supply source for the reactant gas, and a supply source for the inert gas. The gas suppliers GS each further include at least a valve and an MFC that control the supply of cleaning gas and the flow rate of cleaning gas, respectively, for cleaning processing to the corresponding process chamber CH. The gas suppliers GS may each include a supply source for the cleaning gas. Note that, in the present specification, in some cases, the gas for film-forming processing and the gas for cleaning processing are collectively referred to as “processing gas”.

A gas exhauster GE is connected to the process chambers CH1 to CH4.

The gas exhauster GE includes exhaust paths 211 to 214 connected to the process chambers CH1 to CH4, respectively, auto pressure controller (APC) valves 221 to 224, respectively, with which the exhaust paths 211 to 214 are provided, and valves (discs) 231 to 234, respectively, with which the exhaust paths 211 to 214 are provided. The APC valve 221 and the valve 231 are disposed on the exhaust path 211 in this order from the upstream of the exhaust path 211. The APC valve 222 and the valve 232 are disposed on the exhaust path 212 in this order from the upstream of the exhaust path 212. The APC valve 223 and the valve 233 are disposed on the exhaust path 213 in this order from the upstream of the exhaust path 213. The APC valve 224 and the valve 234 are disposed on the exhaust path 214 in this order from the upstream of the exhaust path 214.

The gas exhauster GE further includes connection paths 251 to 253 through which the exhaust paths 211 to 214 are connected upstream of the valves 231 to 234. That is, the exhaust path 211 and the exhaust path 212 are connected through the connection path 251. The exhaust path 212 and the exhaust path 213 are connected through the connection path 252. The exhaust path 213 and the exhaust path 214 are connected through the connection path 253.

Specifically, the exhaust path 211 and the exhaust path 212 are connected upstream of the valves 231 and 232 and downstream of the APC valves 221 and 222 through the connection path 251. The exhaust path 212 and the exhaust path 213 are connected upstream of the valves 232 and 233 and downstream of the APC valves 222 and 223 through the connection path 252. The exhaust path 213 and the exhaust path 214 are connected upstream of the valves 233 and 234 and downstream of the APC valves 223 and 224 through the connection path 253.

The connection paths 251 to 253 are provided with valves 261 to 263, respectively. The APC valves 221 to 224, the valves 231 to 234, and the valves 261 to 263 are connected to the exhaust controller 94. A gas flow path is achieved, mainly, with the exhaust paths 211 to 214 and the connection paths 251 to 253. Note that the gas flow path may include the APC valves 221 to 224, the valves 231 to 234, and the valves 261 to 263.

The APC valves 221 to 224 each have a disc regulatable in the degree of opening and each regulate, in response to an instruction from a pressure controller 94a in the exhaust controller 94, the conductance of the corresponding exhaust path among the exhaust paths 211 to 214 to perform regulation in exhaust flow rate such that the pressure in the corresponding process chamber among the process chambers CH1 to CH4 is controlled.

Vacuum pumps VP1 to VP4 serving as exhausts are disposed downstream of the valves 231 to 234 on the exhaust paths 211 to 214, respectively. Through the gas flow path, the plurality of vacuum pumps (exhausts) VP in parallel is connected to each process chamber CH. The vacuum pumps VP1 to VP4 have sensors SN1 to SN4 attached thereto, respectively. The vacuum pumps VP1 to VP4 may be included in the gas exhauster GE. Hereinafter, if no distinction is particularly needed between the vacuum pumps VP1 to VP4, simply referred to as a “vacuum pump VP”. If no distinction is particularly needed between the sensors SN1 to SN4, simply referred to as a “sensor SN”.

The vacuum pumps VP each include a motor that drives a pump, and the output controller 95 controls the rotational rate (rotational frequency) of the motor. The vacuum pumps VP may be identical in maximum exhaust quantity or at least one of the vacuum pumps VP may be different in maximum exhaust quantity from the others. The vacuum pumps VP each exhaust, in response to an instruction from the output controller 95, the atmosphere in the corresponding process chamber CH.

The sensors SN each detect abnormality, such as a fault, in the corresponding vacuum pump VP. For example, abnormality in a vacuum pump VP does not cause an immediate influence in exhaust capacity but is likely to cause an influence in exhaust capacity (cause an influence on wafer processing) if the operation continues. Abnormality in a vacuum pump VP is detected based on the rotational frequency, power consumption, or temperature of the vacuum pump VP, the pressure of the corresponding exhaust path, among the exhaust paths 211 to 214, near the vacuum pump VP, or any combination thereof. That is, the sensors SN each detect such a parameter as above and outputs a result of the detection to the detector 96. Note that the detector 96 determines abnormality, for example, in response to a drop in rotational frequency, a rise in power consumption, a rise in temperature, or a rise in the pressure of any of the exhaust paths 211 to 214, in comparison to a steady state, and then notifies the emergency controller 97 of the abnormality.

Opening/shutting the valves 261 to 263 enables control of the vacuum pumps VP in parallel connected to each process chamber CH. Opening the valves 231 to 234 and opening the valves 261 to 263 enable each process chamber CH in communication with all the vacuum pumps VP. The number of vacuum pumps VP in communication with each process chamber CH can be changed based on a valve opened among the valves 231 to 234. Note that the number of process chambers CH in communication with each vacuum pump VP can be changed based on a valve opened among the APC valves 221 to 224. That is, a plurality of vacuum pumps VP can be made in communication with one process chamber CH.

The exhaust controller 94 controls the opening/shutting of the valves 231 to 234 and the valves 261 to 263 to control the gas flow in each of the exhaust paths 211 to 214 and the connection paths 251 to 253. Note that the exhaust controller 94 may include the valves 231 to 234 and the valves 261 to 263. The exhaust controller 94 includes the pressure controller 94a, and the pressure controller 94a controls the APC valves 221 to 224 to control the pressure of each process chamber CH. The pressure controller 94a may include the APC valves 221 to 224.

The output controller 95 controls the output (output rate) of each vacuum pump VP. For example, the output rate corresponds to a value of (rotational frequency in operation/maximum rotational frequency) of a vacuum pump VP or a value of (power consumption in operation/maximum power consumption) of a vacuum pump VP.

(2) Substrate Processing Process

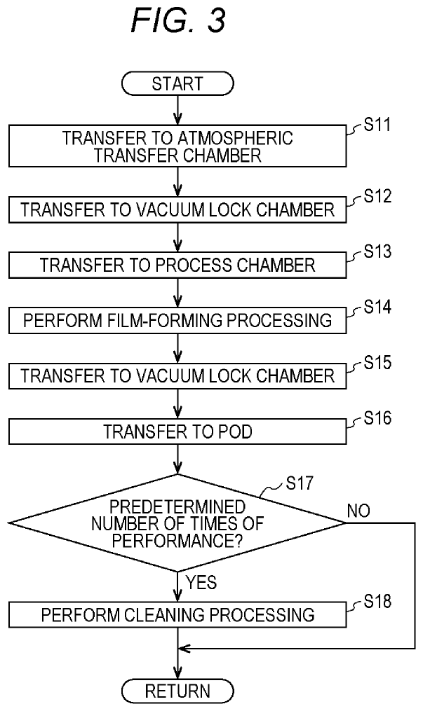

Next, an exemplary substrate processing process that the substrate processing apparatus 1 according to the present embodiment performs will be described with reference to FIG. 3. The following processing is performed based on control of the operation of each constituent in the substrate processing apparatus 1 by the controller CNT.

(S11: Transfer to Atmospheric Transfer Chamber)

First, the atmospheric transfer robot AR transfers a wafer W from the pod PD placed on a load port LP into the atmospheric transfer chamber LM. In this case, the atmospheric transfer chamber LM is supplied with clean air so as to have its inside at approximately atmospheric pressure. Inside the atmospheric transfer chamber LM, the wafer W is placed at a substrate position P2 on the orientation flat aligner OFA, followed by alignment in crystal orientation.

(512: Transfer to Vacuum Lock Chamber)

Next, the atmospheric transfer robot AR picks up the wafer W placed at the substrate position P2 and transfers the wafer W into the vacuum lock chamber VL1 such that the wafer W is placed at a substrate position P9 on the buffer stage ST1. In this case, the gate valves G6 and G7 already remain open. In addition, the gate valves G5 and G8 remain shut, and the vacuum transfer chamber TM, the process chambers CH, and the vacuum lock chamber VL2 each have its inside already vacuum-exhausted.

(S13: Transfer to Process Chamber)

Next, the gate valve G7 is made shut and then the inside of the vacuum lock chamber VL1 is vacuum-exhausted. When the pressure in the vacuum lock chamber VL1 falls to a predetermined pressure, the gate valve G5 is made open with the gate valve G7 shut. Then, the vacuum transfer robot VR picks up the wafer W placed at the substrate position P9 and transfers the wafer W to any process chamber CH of the process chambers CH1 to CH4 such that the wafer W is placed at a substrate position inside the process chamber CH.

(S14: Film-Forming Processing)

When the wafer W is loaded into the process chamber CH, processing gas is supplied into the process chamber CH and film forming processing is performed to the wafer W. Herein, for example, titanium nitride (TiN) is formed as a metal thin film (nitride film or metal nitride film). A method of forming a TiN film will be now outlined.

For example, the following four steps are performed in sequence to perform processing of forming a TiN film. First, titanium (Ti)-containing gas serving as a metallic source is supplied. The flow rate of the Ti-containing gas is, for example, in the range of 0.1 to 1000 sccm due to control of the mass flow controller. The pressure in the process chamber CH is, for example, in the range of 10 to 1500 Pa due to vacuum pumps VP described later. The duration of supply of the Ti-containing gas is, for example, in the range of 0.01 to 300 seconds. The temperature of the wafer W (processing temperature) is regulated, for example, in the range of 350 to 400° C. due to control of a temperature regulator. The supply of the Ti-containing gas causes formation of a Ti-containing layer on the wafer W. Note that the expression of a numerical range such as “10 to 1500 Pa” in the present specification means that the lower limit and the upper limit are included in the range. Therefore, for example, “10 to 1500 Pa” means “not less than 10 Pa and not more than 1500 Pa”. The same applies to other numerical ranges.

Next, the supply of the Ti-containing gas into the process chamber CH is stopped and the inside of the process chamber CH is vacuum-exhausted by the vacuum pumps VP, so that the residual unreacted Ti-containing gas or the residual Ti-containing gas after contributing to the formation of the Ti-containing layer inside the process chamber CH is removed. Note that, in this case, inert gas may be supplied to enhance the effect of removing the Ti-containing gas. Examples of the inert gas that can be used include rare gases, such as argon (Ar) gas, helium (He) gas, neon (Ne) gas, and xenon (Xe) gas, and nitrogen (N₂) gas. The same applies to each step described later.

Next, nitrogen (N)-containing gas (nitriding source or nitriding agent) serving as reactant gas is supplied into the process chamber CH. The flow rate of the N-containing gas is, for example, in the range of 10 to 3000 sccm due to control of the mass flow controller. The pressure in the process chamber CH is, for example, in the range of 10 to 1500 Pa due to the vacuum pumps VP. The duration of supply of the N-containing gas is, for example, in the range of 0.01 to 300 seconds. The temperature of the wafer W (processing temperature) is regulated, for example, in the range of 350 to 400° C. due to control of the temperature regulator. The N-containing gas reacts with at least part of the Ti-containing layer described above. Thus, the Ti-containing layer is nitrided, resulting in formation of TiN.

Next, the supply of the N-containing gas into the process chamber CH is stopped and the inside of the process chamber CH is vacuum-exhausted by the vacuum pumps VP, so that the residual unreacted N-containing gas or the residual N-containing gas after contributing to the nitridation of the Ti-containing layer inside the process chamber CH is removed. Note that, in this case, inert gas may be supplied to enhance the effect of removing the N-containing gas.

For example, the above four steps are repeated by predetermined cycles such that a TiN thin film having a desired thickness is formed. Then, the film-forming processing is completed.

(S15: Transfer to Vacuum Lock Chamber)

In response to completion of the film-forming processing to the wafer W, the gate valve G6 is made open. Then, the vacuum transfer robot VR picks up the processed wafer W placed at the corresponding substrate position among substrate positions P4 to P7 and transfers the processed wafer W into the vacuum lock chamber VL2 such that the processed wafer W is placed at a substrate position P10 on the buffer stage ST2.

(S16: Storage into Pod)

Next, the gate valve G6 is made shut, and clean gas is supplied into the vacuum lock chamber VL2 such that the vacuum lock chamber VL2 has its inside at approximately atmospheric pressure again. In this case, the wafer W may be cooled by a cooler (not illustrated). Then, the gate valve G8 is made open, and the atmospheric transfer robot AR picks up the wafer W placed at the substrate position P10 and stores the wafer W into an empty slot in the pod PD placed on a load port LP.

(S17: Verification of Number of Times of Performance)

Next, made is a determination of whether or not film-forming processing has been performed a predetermined number of times in the same process chamber CH.

(S18: Cleaning Processing)

In a case where film-forming processing has been performed a predetermined number of times, cleaning processing is performed to the process chamber CH to remove a film or by-product adhering in the process chamber CH. After that, the processing is repeated from S11. On the other hand, in a case where film-forming processing has not been performed a predetermined number of times, the processing is repeated from S11 without cleaning processing.

Examples of the Ti-containing gas that can be used include titanium tetrachloride (TiCl₄) gas and titanium tetrafluoride (TiF₄) gas. Examples of the N-containing gas that can be used include nitrogen (N₂) gas, nitrous oxide (N₂O) gas, and gases containing an N—H bond, such as diazene (N₂H₂) gas, hydrazine (N₂H₄) gas, and N₃H₈ gas.

(3) Control of Gas Exhauster

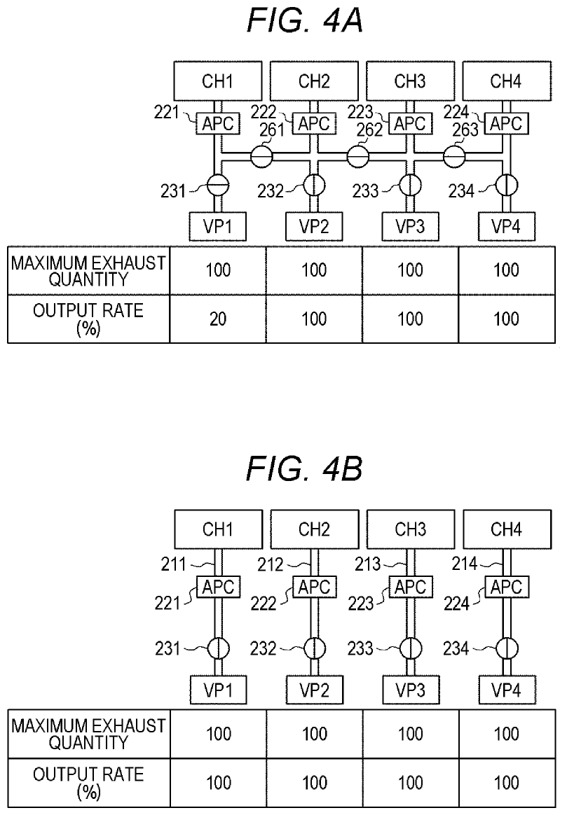

Some examples (connection examples) with a switch in the gas flow path (exhaust path) of the gas exhauster GE and a change in the maximum exhaust quantity or output of a vacuum pump VP will be described with FIGS. 4A and 4B.

A configuration of one-to-one connection of the vacuum pumps VP to the process chambers CH as in FIG. 4B is given as a comparative example to the configuration of connection of the vacuum pumps VP to the process chambers CH according to the present disclosure.

Referring to FIG. 4B, the process chamber CH1 is in communication with the vacuum pump VP1 through the exhaust path 211 on which the APC valve 221 and the valve 231 are disposed. The process chamber CH2 is in communication with the vacuum pump VP2 through the exhaust path 212 on which the APC valve 222 and the valve 232 are disposed. The process chamber CH3 is in communication with the vacuum pump VP3 through the exhaust path 213 on which the APC valve 223 and the valve 233 are disposed. The process chamber CH4 is in communication with the vacuum pump VP4 through the exhaust path 214 on which the APC valve 224 and the valve 234 are disposed.

A reduction in the output (rotational frequency) of a vacuum pump VP in a film-forming process is likely to cause by-products to be deposited in the vacuum pump VP. Thus, use of a vacuum pump VP having a low output causes an increase in the frequency of maintenance of the vacuum pump VP. In the comparative example, even for a process requiring no large exhaust quantity in each process chamber CH, the vacuum pump VP large in capacity is operated at a high output, and excessive exhaustion of the process chamber CH is restricted based on regulation of the exhaust path in the degree of opening by the corresponding APC valve among the APC valves 221 to 224. That is, in the comparative example, the vacuum pumps VP cause excessive power consumption.

A connection example of the gas exhauster illustrated in FIG. 4A corresponds to exemplary exhaustion of four process chambers with three vacuum pumps. The exhaust controller 94 shuts the valve 231 and opens the valves 232 to 234. Thus, the process chambers CH1 to CH4 are in communication with the vacuum pumps VP2 to VP4. The vacuum pumps VP1 to VP4 are identical in maximum exhaust quantity (relative value=100). The output controller 95 causes a drop in the rotational frequency of the vacuum pump VP1 not in communication with any process chamber CH, that is, sets the vacuum pump VP1, for example, at an output rate of 20%, followed by idling operation. A prompter rise can be made in the output rate of the vacuum pump VP1 in idling operation than at an output rate of 0% (completely stopped). The output controller 95 sets the vacuum pumps VP2 to VP4 in communication with the process chambers CH, for example, at an output rate of 100% for maximum output operation.

In the example, although exhaustion of the process chambers CH is performed at a less exhaust quantity than that in the comparative example, the respective output rates of the vacuum pumps VP2 to VP4 are 100%, leading to no promotion of deposition to the vacuum pumps VP. Therefore, a reduction can be made in the power consumption of the vacuum pumps VP, without an increase in the frequency of maintenance of a vacuum pump.

[Control at Time of Abnormality in Vacuum Pump]

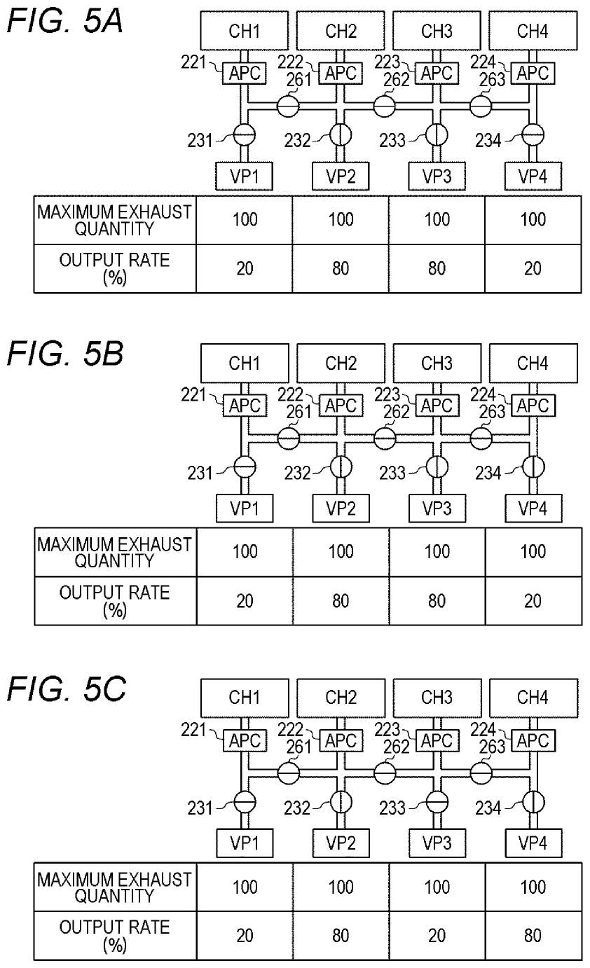

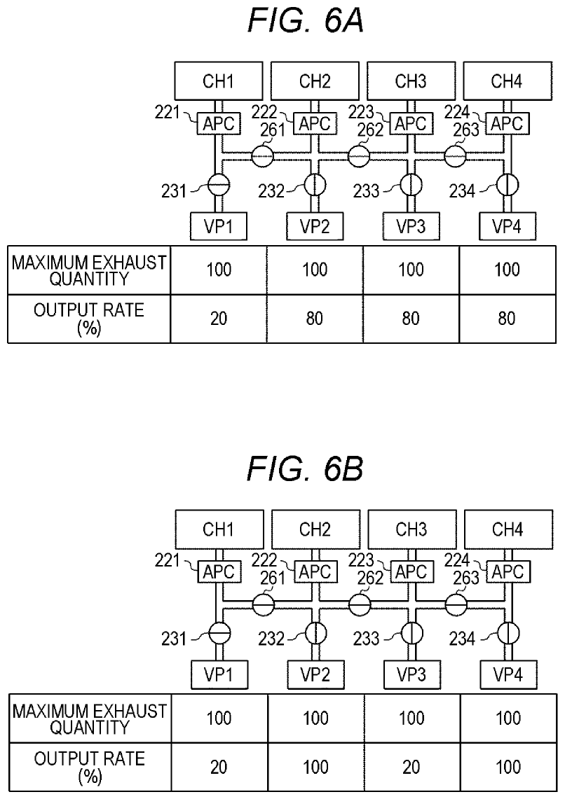

At the time of occurrence of abnormality in a vacuum pump, control of at least either a switch in the gas flow path or a change in the output of a vacuum pump enables continuation of substrate processing. Such a control example will be described with reference to FIGS. 5A to 6B.

Note that, as control at the time of abnormality in a vacuum pump, both control of the gas flow path and control of the output of a vacuum pump may be performed or control of the gas flow path and control of the output of a vacuum pump may be performed in respective separate steps. Some control examples will be descried below.

A control example in a case where abnormality in the vacuum pump VP3 is detected by the detector 96 in the state of the gas exhauster illustrated in FIG. 5A will be described.

The emergency controller 97 controls the exhaust controller 94 such that a transition is made from the state of the gas exhauster illustrated in FIG. 5A to a state where the output of the vacuum pump VP3 remains constant and the flow path is connected to the vacuum pump VP4 with the valve 234 open as in FIG. 5B.

After that, for example, in a case where further abnormality in the vacuum pump VP3 is detected by the detector 96, the emergency controller 97 may control the exhaust controller 94 and the output controller 95 such that the exhauster transitions to a state as illustrated in FIG. 5C. Specifically, the exhaust controller 94 may be controlled such that the flow path is disconnected from the vacuum pump VP3 with the valve 233 shut, and the output controller 95 may be controlled such that the output rate of the vacuum pump VP4 rises from 20% to 80% and the output rate of the vacuum pump VP3 drops from 80% to 20% or the operation of the vacuum pump VP3 stops.

Note that, in the example, in response to detection of abnormality in the vacuum pump VP3 by the detector 96, the exhauster is changed from the state in FIG. 5A to the state in FIG. 5B and then is changed from the state in FIG. 5B to the state in FIG. 5C, but this is not limiting. The exhauster may be changed from the state in FIG. 5A to the state in FIG. 5C.

Such control enables observation of a change in the state of the vacuum pump VP3 with the vacuum pump VP3 continuing operating against further abnormality in the vacuum pump VP3. In addition, the exhauster can be controlled based on the progress of processing in each process chamber CH.

Next, a control example in a case where abnormality in the vacuum pump VP3 is detected by the detector 96 in the state of the gas exhauster illustrated in FIG. 6A will be described.

The emergency controller 97 controls the output controller 95 such that the output rate of the vacuum pump VP3 drops from 80% to 20% and the output rate of the vacuum pump VP2 rises from 80% to 100%, as illustrated in FIG. 6B, in the state of the gas exhauster illustrated in FIG. 6A. Such control enables a drop in the output of the vacuum pump in which abnormality is detected, with no change in the exhaust quantity of each process chamber CH, against further abnormality in the vacuum pump VP3. In addition, the exhauster can be controlled based on the progress of processing in each process chamber CH.

[Control Based on Information on Processing in Process Chamber]

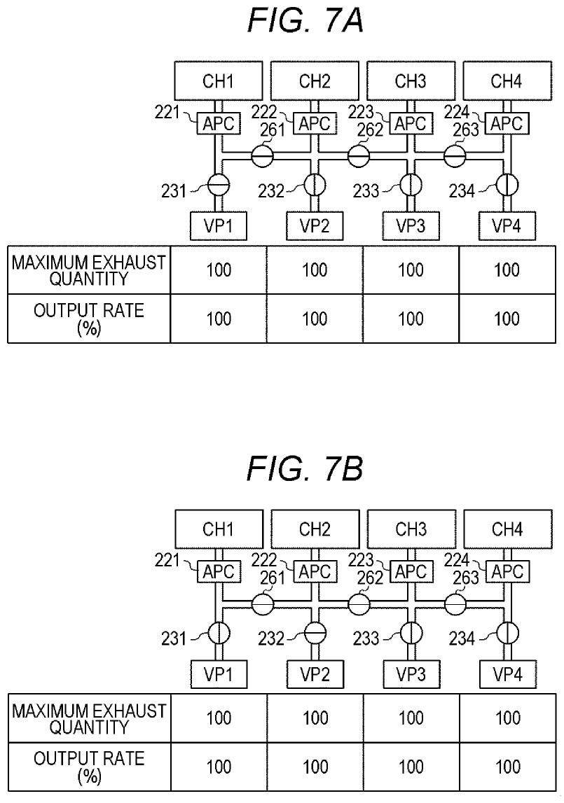

A control example in which at least either a switch in the gas flow path or a change in the output of a pump is controlled based on information on processing performed in a process chamber CH will be described with reference to FIGS. 7A to 10B.

The controller CNT may control at least either the exhaust controller 94 or the output controller 95 between first processing performed in a process chamber CH and second processing performed in the process chamber CH after the first processing.

The controller CNT may control the exhaust controller 94 and the output controller 95 between the first processing and the second processing such that at least part of the vacuum pumps VP performing exhaustion of the process chamber CH is replaced with another vacuum pump VP. In other words, the exhaustion of the process chamber CH may be performed in the second processing with a vacuum pump different from a vacuum pump used in the first processing.

For example, the exhaust controller 94 may be controlled between the first processing and the second processing such that a change is made from the state of operation of the vacuum pumps VP1 and VP2 in the exhauster illustrated in FIG. 7A to the state of operation of the vacuum pumps VP1 and VP2 in the exhauster illustrated in FIG. 7B. In this case, even when part of the vacuum pumps VP performs no exhaustion, the exhaustion of all the process chambers CH can continue. Therefore, a reduction can be made in the frequency of maintenance of a vacuum pump VP with no decrease in productivity.

The controller CNT may control the exhaust controller 94 and the output controller 95 between the first processing and the second processing such that the gas flow rate per unit of time for exhaustion of the process chamber CH varies between in the first processing and in the second processing.

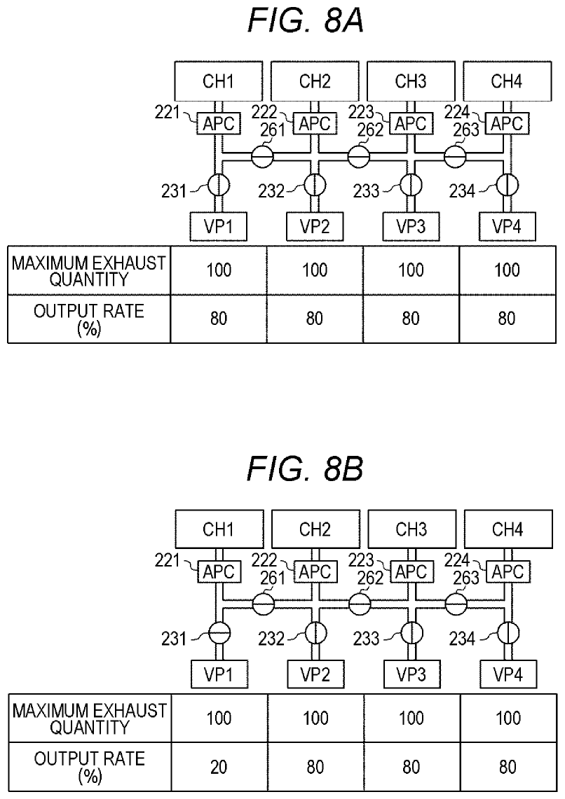

For example, for a change in gas flow rate, the exhaust controller 94 and the output controller 95 may be controlled such that the state of the exhauster in FIG. 8A is brought to a state as in FIG. 8B. That is, the gas flow rate may be changed due to a change in the number of vacuum pumps VP for exhaustion. In this case, although exhaustion of the process chambers CH is performed at a less exhaust quantity in FIG. 8B than in FIG. 8A, the respective output rates of the vacuum pumps VP2 to VP4 are 80%. Thus, deposition to the vacuum pumps VP is hardly promoted. Therefore, a reduction can be made in the power consumption of the vacuum pumps VP, without an increase in the frequency of maintenance of a vacuum pump.

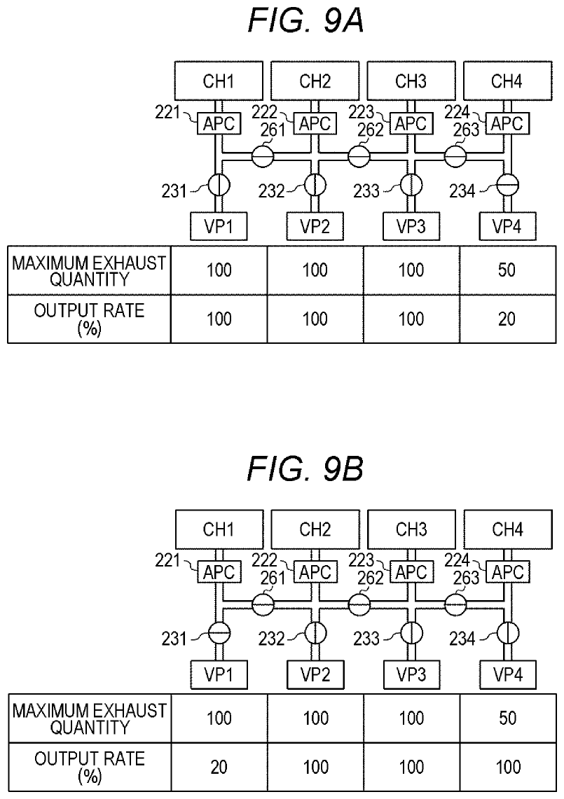

For example, for a change in gas flow rate, the exhaust controller 94 may control the opening/shutting of the valves 231 and 234 and the output controller 95 may control the respective output rates of the vacuum pumps VP1 and VP4 such that the state of the exhauster in FIG. 9A is brought to a state as in FIG. 9B. That is, the gas flow rate may be changed by connection of a vacuum pump VP different in maximum exhaust quantity to the process chambers CH. In this case, although exhaustion of the process chambers CH is performed at a less exhaust quantity in FIG. 9B than in FIG. 9A, the respective output rates of the vacuum pumps VP2 to VP4 are 100%. Thus, deposition to the vacuum pumps VP is hardly promoted. Therefore, a reduction can be made in the power consumption of the vacuum pumps VP, without an increase in the frequency of maintenance of a vacuum pump.

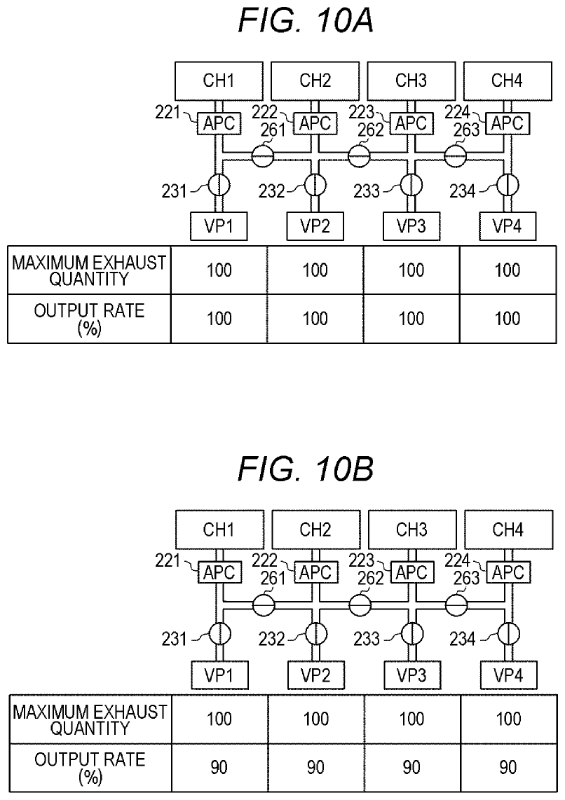

For example, for a change in gas flow rate, the output controller 95 may control the respective output rates of the vacuum pumps VP1 to VP4 such that the state of the exhauster in FIG. 10A is brought to a state as in FIG. 10B. That is, the gas flow rate may be changed based on the output rates of the vacuum pumps VP for exhaustion. In this case, although exhaustion of the process chambers CH is performed at a less exhaust quantity in FIG. 10B than in FIG. 10A, the respective output rates of the vacuum pumps VP1 to VP4 are 90%. Thus, deposition to the vacuum pumps VP is hardly promoted. Therefore, a reduction can be made in the power consumption of the vacuum pumps VP, without an increase in the frequency of maintenance of a vacuum pump.

The first processing may correspond to first substrate processing, and the second processing may correspond to second substrate processing. For example, the first substrate processing and the second substrate processing may be film-forming processing and annealing, respectively. Alternatively, the first substrate processing and the second substrate processing may be identical in the type of a film to be formed in a process and may be different in the aspect ratio of a recess with which a substrate is provided.

One of the first processing and the second processing may be substrate processing and the other may be cleaning processing to the process chamber CH. The exhaust quantity is less in cleaning processing to the process chamber CH than in substrate processing, and thus selection of a vacuum pump VP or a change in the output of a vacuum pump VP enables minimum power consumption.

One of the first processing and the second processing may be substrate processing and the other may be remaining on standby. The exhaust quantity is less and deposition is less likely to occur in a state where no substrate is present in the process chamber CH than in substrate processing, and thus selection of a vacuum pump VP or a change in the output of a vacuum pump VP enables minimum power consumption.

The first processing and the second processing may be the same processing.

The embodiment of the present disclosure has been specifically described above, but the present disclosure is not limited to the above-described embodiment. Thus, various modifications can be made without departing from the gist of the present disclosure. The above-described embodiment and modified examples can be used in appropriate combination. For example, such a case can be made similar in processing procedure and processing conditions to the above-described embodiment and modified examples.

In the above-described embodiment, an exemplary case where a thin film is formed on the surface of a substrate as a substrate processing process has been given mainly, but the present disclosure is not limited to this. That is, the present disclosure can be applied to film-forming processing not for the exemplified thin film in the above-described embodiment, in addition to the exemplary thin-film forming in the above-described embodiment. The present disclosure can be applied to any substrate processing, namely, various types of substrate processing, such as heat treatment (annealing), plasma processing, diffusing, oxidizing, nitriding, lithography, and reflowing for carrier activation or planarization after ion implantation, in addition to film-forming processing.

In the above-described embodiment, given has been an example of forming a film with the substrate processing apparatus serving as a cluster-type apparatus including a plurality of single-wafer processing units, in which a single substrate is processed at a time in each single-wafer processing unit. The present disclosure is not limited to the above-described embodiment and thus can be applied preferably to, for example, forming a film with a substrate processing apparatus including a plurality of processing unit, in which a plurality of substrates is processed at a time in each processing unit or forming a film with a substrate processing apparatus including a batch-type processing unit in which a plurality of substrates is processed at a time. In the above-described embodiment, given has been an example of forming a film with the substrate processing apparatus including a cold-wall type process furnace. However, the present disclosure is not limited to the above-described embodiment and thus can be applied preferably to forming a film with a substrate processing apparatus including a hot-wall type process furnace.

Even in a case where such substrate processing apparatuses are each used, the corresponding processing can be performed in accordance with a processing procedure and processing conditions similar to those in the above-described embodiment, leading to obtainment of an effect similar to that in the above-described embodiment.

According to the present disclosure, a reduction can be made in the power consumption of a vacuum pump.

What is claimed is:

1. A substrate processing apparatus comprising:
a process chamber in which a substrate is processed;
an exhaust controller configured to control a gas flow path through which a plurality of exhausts in parallel is connected to the process chamber and a gas flow in the gas flow path;
an output controller configured to control output of each of the exhausts; and
a controller configured to be capable of controlling the exhaust controller and the output controller.

2. The substrate processing apparatus according to claim 1, wherein the exhaust controller includes a pressure controller configured to regulate a degree of opening of the gas flow path to control a pressure of the process chamber to a predetermined pressure.

3. The substrate processing apparatus according to claim 1, wherein at least one of the plurality of exhausts is different in maximum exhaust quantity from another of the exhausts.

4. The substrate processing apparatus according to claim 1, wherein the process chamber includes a plurality of process chambers in which respective substrates are processed, and the plurality of exhausts in parallel is connected to each of the process chambers through the gas flow path.

5. The substrate processing apparatus according to claim 1, further comprising:
a detector configured to detect abnormality in the exhausts; and
an emergency controller configured to be capable of controlling, in response to detection of the abnormality in the exhausts by the detector, at least either the exhaust controller or the output controller.

6. The substrate processing apparatus according to claim 1, wherein the controller is configured to be capable of controlling at least either the exhaust controller or the output controller between first processing performed in the process chamber and second processing performed in the process chamber after the first processing.

7. The substrate processing apparatus according to claim 6, wherein the controller is configured to be capable of controlling at least either the exhaust controller or the output controller such that exhaustion of the process chamber is performed in the second processing by an exhaust in the exhausts, the exhaust being different from an exhaust used in the first processing in the exhausts.

8. The substrate processing apparatus according to claim 6, wherein the controller is configured to be capable of controlling at least either the exhaust controller or the output controller such that a gas flow rate per unit of time for exhaustion of the process chamber varies between in the first processing and in the second processing.

9. The substrate processing apparatus according to claim 8, wherein the controller is configured to be capable of controlling at least either the exhaust controller or the output controller such that a number of the exhausts connected to the process chamber varies between in the first processing and in the second processing.

10. The substrate processing apparatus according to claim 8, wherein the controller is configured to be capable of controlling at least either the exhaust controller or the output controller such that at least one exhaust of the exhausts connected to the process chamber varies in maximum exhaust quantity between in the first processing and in the second processing.

11. The substrate processing apparatus according to claim 8, wherein the controller is configured to control at least either the exhaust controller or the output controller such that an output rate that is a value of the output to a maximum output of at least one exhaust of the exhausts connected to the process chamber varies between in the first processing and in the second processing.

12. The substrate processing apparatus according to claim 6, wherein the first processing corresponds to first substrate processing, and the second processing corresponds to second substrate processing.

13. The substrate processing apparatus according to claim 6, wherein one of the first processing and the second processing corresponds to substrate processing, and another corresponds to cleaning processing to the process chamber.

14. The substrate processing apparatus according to claim 6, wherein one of the first processing and the second processing corresponds to substrate processing and another corresponds to remaining on standby.

15. A method of processing a substrate, comprising:
processing a substrate in a process chamber; and
controlling at least either a gas flow in a gas flow path through which a plurality of exhausts in parallel is connected to the process chamber or output of the plurality of exhausts.

16. A method of manufacturing a semiconductor device comprising the method of claim 15.

17. A non-transitory computer-readable recording medium storing a program that causes, by a computer, a substrate processing apparatus to perform a process comprising:
processing a substrate in a process chamber; and
controlling at least either a gas flow in a gas flow path through which a plurality of exhausts in parallel is connected to the process chamber or output of the plurality of exhausts.
